(19) United States
(12) Patent Application Publication
(10) Pub. No.: US 2004/0129218 A1
(43) Pub. Date: Jul. 8, 2004

(54) Exhaust ring mechanism and plasma processing apparatus using the same

(76) Inventors: Toshiki Takahashi, Esashi-shi (JP); Kazuyuki Tezuka, Nirasaki-shi (JP); Takashi Kitazawa, Nirasaki-shi (JP); Norihiko Amikura, Nirasaki-shi (JP); Hiroshi Koizumi, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/739,351

(22) Filed: Dec. 19, 2003

Related U.S. Application Data
(63) Continuation-in-part of application No. PCT/JP02/12826, filed on Dec. 6, 2002.

(30) Foreign Application Priority Data
Dec. 7, 2001 (JP) 2001-373858
Dec. 19, 2002 (JP) 2002-368012

(51) Int. Cl. C23C 16/00; C23F 1/00

(52) U.S. Cl. 118/715; 156/345.29; 156/345.26; 118/728

(57) ABSTRACT

The invention comprises a lower electrode which is disposed in a processing chamber and holds a wafer W, and an exhaust ring mechanism disposed between the lower electrode and an inner wall of the processing chamber, wherein the exhaust ring mechanism has an exhaust ring, and a magnetic field forming section which forms a magnetic field parallel to the principal plane of the exhaust ring, and thereby preventing plasma leak from a plasma region to a non-plasma region by the formed magnetic field, and a plasma processing apparatus using the exhaust ring mechanism.

### CROSS REFERENCE TO RELATED APPLICATIONS

This is a Continuation-in-Part Application of PCT Application No. PCT/JP02/12826, filed Dec. 6, 2002, which was not published under PCT Article 21(2) in English.

This application is based upon and claims the benefit of priority from the prior Japanese Patent Applications No. 2001-373858, filed Dec. 7, 2001; and No. 2002-368012, filed Dec. 19, 2002, the entire contents of both of which are incorporated herein by reference.

### BACKGROUND OF THE INVENTION

1. Field of the Invention

The present invention relates to a plasma processing apparatus, and more particularly to an exhaust ring mechanism for use in a plasma processing apparatus capable of confining a plasma in a plasma region and such plasma processing apparatus.

2. Description of the Related Art

The plasma processing apparatus is an apparatus for treating an object such as wafers by using a plasma generated in a processing chamber by etching or film forming process. The plasma processing apparatus includes various types such as capacitive coupling type and inductive coupling type.

As the plasma processing apparatus of capacitive coupling type, a parallel flat plate type of electrodes is widely used. The parallel flat plate type plasma processing apparatus comprises a processing chamber capable of keeping in a vacuum state by an exhaust system including a vacuum pump. This processing chamber incorporates a holder which serves also as a lower electrode on which the object such as wafers is mounted. An upper electrode is disposed above the holder across a space (processing space). A high frequency power source for applying a high frequency electric power is connected to either upper or lower electrode, or both upper and lower electrodes. A focusing ring is provided on the outer peripheral edge of the holder.

In this configuration, in the processing chamber at high degree of vacuum, high frequency power is applied to either upper or lower electrode or both electrodes from the high frequency power source, and a plasma is generated in the atmosphere by a process gas introduced in the processing chamber, so that the object is etched or processed by plasma.

An exhaust ring with plural exhaust holes is provided between the inner peripheral walls of the holder and processing chamber, and byproducts and unwanted (used) process gas are uniformly exhausted from around the plasma region through the exhaust holes of the exhaust ring.

The processing chamber is separated into the plasma region and non-plasma region via the exhaust ring. Since, at the plasma region side, the processing chamber inner wall is spent by sputtering by plasma ions, or contaminated with deposits of byproducts or the like, the inner wall is treated by ceramic spaying. On the other hand, since the non-plasma region is almost free from attack of plasma ions, and is rarely contaminated by byproducts, such treatment is not needed in the processing chamber inner wall.

In the exhaust ring, however, since exhaust holes are formed on the whole periphery, when the plasma is enhanced in density, plasma leaks into the non-plasma region through the exhaust holes. By this plasma leak, the plasma density is lowered in the outer peripheral edge of the object, and as a result, the uniformity of plasma processing such as an etching rate is spoiled. Such plasma leak may also lead to damage or contamination of the processing chamber inner wall in the non-plasma region.

As a countermeasure, it has been proposed to prevent plasma leak by decreasing the total area of the exhaust holes, but in this method, to the contrary, the gas exhaust volume from the plasma region is limited, and byproducts are not discharged sufficiently. In particular, exhaust from a pressure close to an atmospheric pressure after release to the atmosphere or after nitrogen gas purge, it takes a longer exhaust time until reaching a predetermined degree of vacuum, and the throughput may be lowered.

The plasma etching apparatus comprises an exhaust mechanism for evacuating the plasma processing chamber to a predetermined degree of vacuum. In such an exhaust mechanism, it is required to enhance the uniformity of processing within the substrate surface to be processed as means for forming a process gas flow as uniformly as possible around the substrate mounted on a platform.

For this purpose, an annular exhaust ring having multiple exhaust holes is disposed around the platform, and it is designed to evacuate from beneath the exhaust ring. For example, see Jpn. Pat. Appln. KOKAI Publication No. 7-245295.

In the plasma etching apparatus, leak of plasma from the plasma processing chamber is prevented by this exhaust ring, and therefore, the diameter of the exhaust holes is relatively small, about 1.5 mm. For example, as shown in FIG. 18, an exhaust ring 401 has a multiplicity of (for example, at least ten thousand) exhaust holes 400 of the above-described uniform and small size radially formed on a annular plate.

By disposing such an annular exhaust ring in the processing chamber, it is attempted to form a uniform flow of process gas. This exhaust ring functions also prevent leak of plasma from the plasma processing chamber.

By the use of such an exhaust ring, however, the exhaust efficiency is lowered. Accordingly, it has been demanded to enhance the conductance of the exhaust ring and enhance the exhaust efficiency.

### BRIEF SUMMARY OF THE INVENTION

It is hence an object of the invention to provide an exhaust ring mechanism capable of enhancing the conductance, enhancing the exhaust efficiency, and confining a plasma within a plasma region of a processing chamber, and a plasma processing apparatus provided with the exhaust ring.

The invention provides an exhaust ring mechanism which contacts with the plasma region in order to execute plasma process to an object to be processed in a processing chamber, and forms a product gas exhausts passage in the plasma region. This exhaust ring mechanism comprises an exhaust ring having a surface contacting with the plasma region, and a magnetic field forming section which forms a magnetic field having a line of magnetic force parallel to the direction of the surface of the exhaust ring, in which passing of plasma ions and electrons is blocked by the formed magnetic field, and the plasma is confined within the plasma region, so that leak of plasma from the plasma region to a non-plasma region can be prevented. As a result, plasma diffusion is prevented, and the uniformity of the plasma density in a peripheral edge of a wafer W and a central part of the wafer W can be enhanced. Moreover, lowering of plasma processing such as etching in an outer peripheral edge of the wafer W is prevented, and the uniformity of plasma processing within the surface is maintained.

### BRIEF DESCRIPTION OF THE SEVERAL VIEWS OF THE DRAWING

FIG. 1 is a diagram showing a configuration of a plasma processing apparatus and an exhaust ring mechanism according to a first embodiment of the invention.

FIG. 2A is a plan view showing a part for explaining the action of the exhaust ring mechanism shown in FIG. 1, FIG. 2B is a sectional view in the radial direction of FIG. 2A, and FIG. 2C is a sectional view in the peripheral direction of FIG. 2A.

FIG. 3A is a plan view showing a part of an exhaust ring mechanism according to a second embodiment of the invention, FIG. 3B is a sectional structural view in the radial direction of FIG. 3A, and FIG. 3C is a sectional structural view in the peripheral direction of FIG. 3A.

FIG. 4A is a plan view showing a part of an exhaust ring mechanism according to a third embodiment of the invention, and FIG. 4B is a sectional structural view in the radial direction of FIG. 4A.

FIG. 5A is a plan view showing a part of a configuration of an exhaust ring mechanism according to a fourth embodiment of the invention, and FIG. 5B is a diagram showing the direction of a magnetic field vector in the configuration of FIG. 5A.

FIG. 6A is a view showing a partial plane of a plane configuration of an exhaust ring mechanism according to a fifth embodiment of the invention, and FIG. 6B is a diagram showing the direction of a magnetic field vector in the configuration of FIG. 6A.

FIG. 7A is a view showing a partial plane of a plane configuration of an exhaust ring mechanism according to a sixth embodiment of the invention, FIG. 7B is a diagram of a first example of magnet layout, and FIG. 7C is a diagram of a second example of magnet layout.

FIG. 8A is a plane configuration view as seen from above an exhaust ring of an exhaust ring mechanism according to a seventh embodiment of the invention, FIG. 8B is a diagram showing an example of magnet layout and the direction of a magnetic field vector in the configuration of FIG. 8A, and FIG. 8C is a diagram explaining the concept of formation of a magnetic field according to the embodiment.

FIG. 9A is a plane configuration view as seen from above an exhaust ring of an exhaust ring mechanism according to an eighth embodiment of the invention, and FIG. 9B is a diagram showing an example of magnet layout and the direction of a magnetic field vector in the configuration of FIG. 9A.

FIG. 10A is a plane configuration view as seen from above an exhaust ring of an exhaust ring mechanism according to a ninth embodiment of the invention, and FIG. 10B is a diagram showing an example of magnet layout and the direction of a magnetic field vector in the configuration of FIG. 10A.

FIG. 11A is a view showing an outer appearance of a deposit shield mechanism to which a function of the exhaust ring mechanism in the above-described embodiments is applied, FIG. 11B is a plane configuration view as seen from above of the deposit shield in FIG. 11A, FIG. 11C is a side view showing an outer appearance of the deposit shield in FIG. 11A, and FIG. 11D is a partial sectional view showing a configuration of magnets arranged in the radial direction in the deposit shield.

FIG. 12A is a view showing an outer appearance of a deposit shield mechanism to which a function of the exhaust ring mechanism in the above-described embodiments is applied, FIG. 12B is a plane configuration view as seen from above the deposit shield in FIG. 12A, FIG. 12C is a side view showing an outer appearance of the deposit shield in FIG. 12A, and FIG. 12D is a partial sectional view showing an configuration of magnets arranged in the peripheral direction in the deposit shield.

FIG. 13 is a general schematic diagram showing a configuration of a vacuum processing apparatus according to a tenth embodiment of the invention.

FIG. 14 is an essential schematic diagram of the vacuum processing apparatus in FIG. 13.

FIG. 15 is a diagram showing a modified example of the essential schematic configuration of the vacuum processing apparatus in FIG. 13.

FIG. 16 is a diagram showing a modified example of the essential schematic configuration of the vacuum processing apparatus in FIG. 13.

FIG. 17 is a diagram showing a modified example of the essential schematic configuration of the vacuum processing apparatus in FIG. 13.

FIG. 18 is a view showing an essential schematic configuration of a vacuum processing apparatus in a prior art.

### DETAILED DESCRIPTION OF THE INVENTION

Embodiments of the invention will be specifically described below.

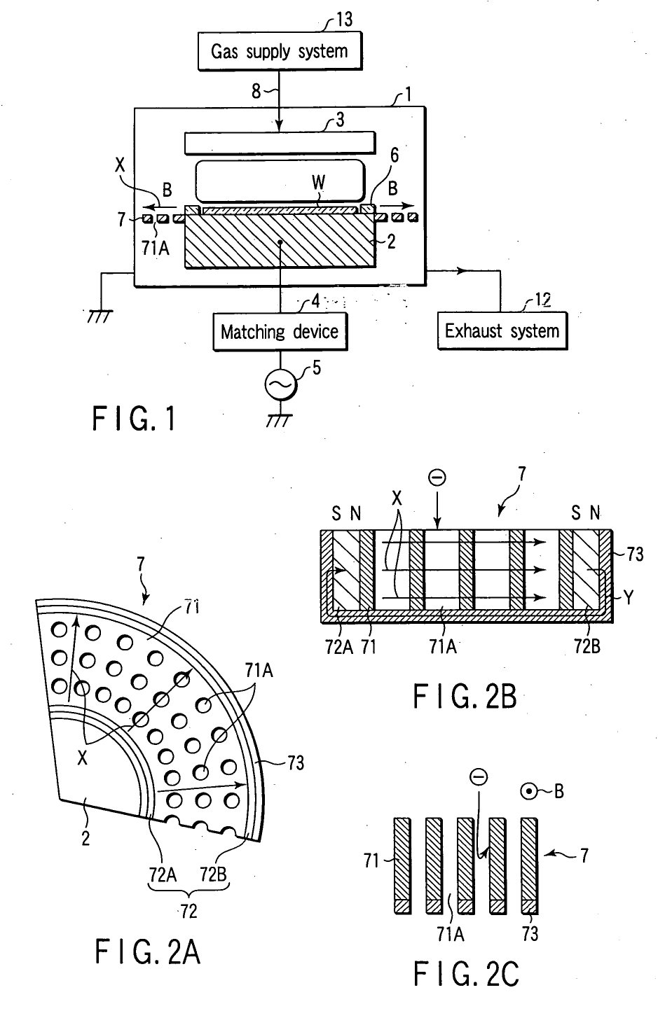

FIG. 1 is a diagram schematically showing a plasma processing apparatus and an exhaust ring mechanism according to a first embodiment of the invention. FIG. 2A is a plan view showing a part of a configuration of an exhaust ring mechanism 7, FIG. 2B is a sectional view thereof along its radial direction, and FIG. 2C is a sectional view thereof along its peripheral direction.

This plasma processing apparatus is roughly comprised of, as shown in FIG. 1, a processing chamber 1, a holder 2, an upper electrode 3, a matching device 4, a high frequency power source 5, a focus ring 6, an exhaust ring mechanism 7, an exhaust system 12, and a gas supply system (purge gas and process gas) 13.

The processing chamber 1 is formed of a conductive material such as aluminum, and has an airtight structure for maintaining a predetermined high degree of vacuum. An inner wall to be exposed to a plasma is treated by known corrosive preventive measure such as alumite treatment.

The holder 2 is disposed in the processing chamber 1, an object (such as a wafer) W is put on, and it is held by an electrostatic chuck mechanism (not shown). It also has a transfer mechanism (not shown), and the wafer is transferred to a waver conveying mechanism (not shown). The high frequency power source 5 is connected to the holder 2 by way of the matching device 4 described below, and it also functions as a lower electrode to which a high frequency electric power is applied for generating a plasma. Therefore, the holder 2 is called the lower electrode 2 thereinbelow.

The focus ring 6 is disposed on an outer peripheral edge of a platform to which the wafer on the lower electrode 2 is mounted. The focus ring 6 is made of silicone or the like, and formed like a ring, and the wafer is fitted to the inside of the ring 6. By this focus ring 6, the plasma generated between the lower electrode 2 and the upper electrode 3 can be focused on the wafer W.

The upper electrode 3 is disposed in the upper part of the processing chamber 1 so as to be opposite and parallel to the platform of the lower electrode across a predetermined gap above the lower electrode 2. The upper electrode 3 has a hollow box shape, and functions to supply gas by diffusing the process gas, for example, etching gas like a shower into the processing chamber.

The high frequency power source 5 applies a high frequency electric power of, for example, 13.56 MHz to the lower electrode 2. The matching device 4 is disposed between the high frequency power source 5 and the lower electrode 2, and functions to match the impedance between the upper electrode and the lower electrode during discharge, thereby minimizing the loss of the applied high frequency power by reflection waves or the like. When the matched high frequency power is applied in the process atmosphere of the process gas supplied in the-processing chamber 1, a plasma is generated between the lower electrode 2 and the upper electrode 3.

The exhaust ring mechanism 7 is formed like a ring around the outer periphery (outer periphery of the focus sing 6) on the platform of the lower electrode 2. By the upper and lower sides of the principal plane of the exhaust ring mechanism 7, the processing chamber 1 is separated into a plasma region and a non-plasma region. Herein, the plasma region is formed above the upper side of the exhaust ring mechanism 7, and the non-plasma region is below the lower side.

The exhaust ring mechanism 7 includes, as shown in FIGS. 2A and 2B, an exhaust ring 71, and a magnetic field forming section 72 for forming a magnetic field in a principal plane direction in the exhaust ring 71 (direction parallel to the exhaust ring principal plane). Herein, the platform of the lower electrode 2 and the exhaust ring principal plane are parallel to each other. The exhaust ring mechanism 7 contacts with the plasma region for processing the wafer W by plasma in the processing chamber 1, and forms an exhaust passage of process gas in the plasma region.

The exhaust ring 71 has a plurality of circular exhausts holes 71A formed in uniform dispersion on the whole periphery as shown in the diagram, and the gas in the plasma region is exhausted from these exhaust holes 71A to outside of the processing chamber 1 by way of the non-plasma region. In this example, the exhaust holes are formed in triple rings in the peripheral directions, but not limited to this layout, the holes may be formed uniformly in the principal plane of the exhaust ring, and the layout is not particularly predetermined as far as the exhaust capacity and characteristic are sufficiently taken into consideration.

The magnetic field forming section 72 of the embodiment is composed of, as shown in FIG. 2A, a first ring magnet 72A (permanent magnet or electromagnet) covering the inner periphery of the exhaust ring 71, and a second ring magnet 72B (permanent magnet or electromagnet) covering the outer periphery of the exhaust ring 71. In this configuration, as shown in FIG. 2B, the magnetic field forming section 72 forms a magnetic field in a direction parallel to the principal plane toward the inner wall of the processing chamber 1 from the lower electrode 2 in the exhaust ring 71. This magnetic field confines the generated plasma within the plasma region and prevents leak of the plasma into the non-plasma region.

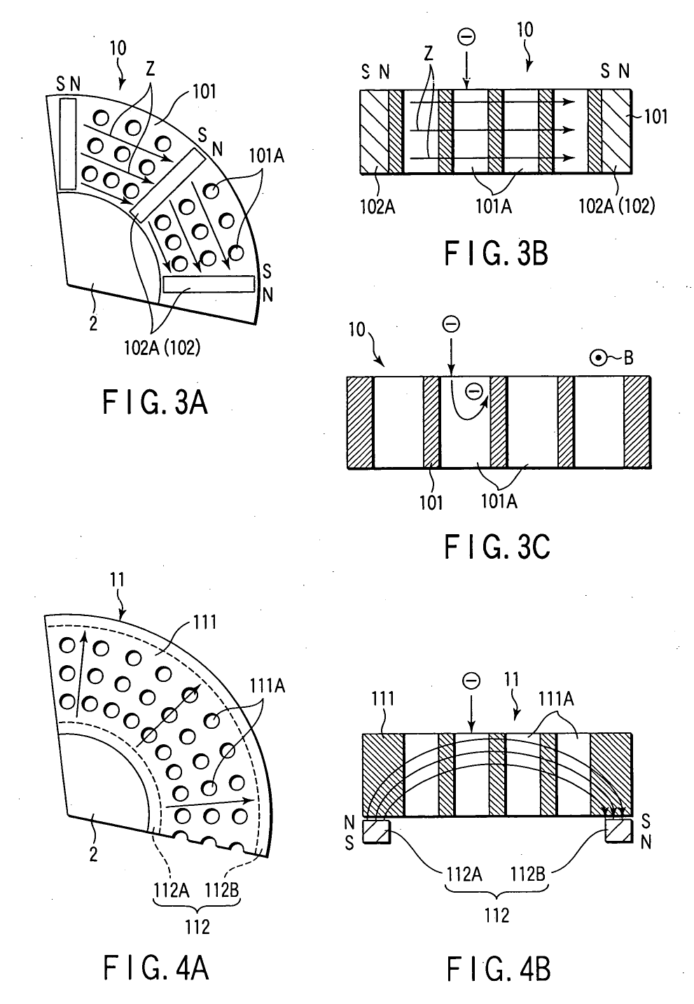

More specifically, between the first ring magnet 72A and the second ring magnet 72B, as indicated by arrow X in FIG. 2A, a magnetic field is formed in a direction parallel to the principal plane from the first ring magnet 72A to the second ring magnet 72B. Since a line of magnetic force B of this magnetic field is substantially orthogonal to the leak direction of plasma ions and electrons, even if plasma ions or electrons in the plasma region are moved to pass through the exhaust holes 71A of the exhaust ring 71 as shown in FIG. 2B, the plasma ions and electrons are controlled by the action of the magnetic field as shown in FIG. 3C, and revolve about the line of magnetic force B. In FIGS. 2B and 2C, only minus ions are shown. It is the same in the following embodiments.

The plasma ions and electrons impinge on the inner periphery of the exhausts holes 71A, do not leak out to the non-plasma region, and are hence confined within the plasma region. Therefore, diffusion of the plasma is prevented on the outer peripheral edge of the wafer W, and the uniformity of the plasma density in the peripheral edge of the wafer W and the central part of the wafer W can be maintained. Accordingly, decline of processing speed (etching rate) of etching or the like on the outer peripheral edge of the wafer W is prevented, and the in-plane uniformity of plasma processing can be enhanced.

The exhaust ring mechanism 7 also includes a magnetic field sealing section 73 as shown in FIGS. 2A and 2B. This magnetic field sealing section 73 is made of a magnetic material such as iron, and is formed as a magnetic container for integrally accommodating the exhaust ring 71, and first and second ring magnets 72A, 72B as shown in the drawing. Hereinafter, the magnetic field sealing section 73 is called a magnetic container 73.

By this magnetic container 73 for accommodating integrally, as shown in FIG. 2B, a magnetic path Y is formed from its outer periphery to the inner periphery, and magnetic field leak from the exhaust ring 71 can be prevented, so that the magnetic field can be utilized effectively. As a result, the plasma can be confined within the plasma region more securely.

Therefore, the uniformity of plasma processing can be further enhanced by securely confining the plasma ions and electrons in the processing chamber 1 within the plasma region. It is also effective to protect the inner wall of the processing chamber 1 in the non-plasma region from damage by plasma, and prevent from contamination by byproducts.

Since the first ring magnet 72A is adjacent to the lower electrode 2, a magnetic field acts also on the outer peripheral edge on the top of the lower electrode 2, and this magnetic field can further enhance the in-plane uniformity of plasma processing such as etching rate during etching of the outer peripheral edge of the wafer W.

According to the first embodiment, as explained herein, the exhaust ring mechanism 7 forms a magnetic field in the radial direction of the processing chamber, the formed magnetic field acts even if plasma ions or electrons are moved to pass through the exhaust holes of the exhaust ring, the plasma ions and electrons are caused to revolve and impinge in the exhaust holes, and passing of plasma ions and electrons is prevented, so that the plasma can be securely confined within the plasma region.

Therefore, diffusion of the plasma on the outer peripheral edge of the wafer W is prevented, and the uniformity of the plasma density in the peripheral edge of the wafer W and the central part of the wafer W can be enhanced. Further, decline of plasma processing such as etching on the outer peripheral edge of the wafer W is prevented, and the in-plane uniformity of plasma processing can be maintained.

The inner wall of the processing chamber 1 in the non-plasma region can be protected from plasma damage and contamination by byproducts can be prevented. Also on the outer peripheral edge on the top of the lower electrode 2, a magnetic field is formed by the magnetic field forming section, and the uniformity of plasma processing such as etching rate can be enhanced by the effect of this magnetic field. Further, since the exhaust ring and first and second ring magnets are integrally accommodated in the magnetic container, leak of the magnetic field is prevented by the magnetic container, and the magnetic field can be utilized effectively without waste, so that the plasma can be confined more securely within the plasma region.

An exhaust ring mechanism for use in a plasma processing apparatus according to a second embodiment of the invention will be described. FIG. 3A is a plan view showing a part of a configuration of the exhaust ring mechanism according to the second embodiment of the invention, FIG. 3B is a sectional structural view in the radial direction of the processing chamber in FIG. 3A, and FIG. 3C is a sectional structural view in its peripheral direction of FIG. 3A.

An exhaust ring mechanism 10 for use in this plasma processing apparatus comprises an exhaust ring 101 and a magnetic field forming section 102 as shown in FIGS. 3A and 3B. The magnetic field forming section 102 is composed of a plurality of magnets 102A disposed radially at a predetermined interval in the peripheral direction of the exhaust ring 101. Each magnet 102A is formed like a plate, and is provided to fill in slits formed in the exhaust ring 101. Between mutually adjacent magnets 102A of the exhaust ring 101, a magnetic field is formed in a direction parallel to the exhaust ring principal plane in a clockwise rotating direction (CW) as indicated by arrow Z in FIG. 3A.

A line of magnetic force B of this magnetic field is substantially orthogonal to the leak direction of plasma and electrons. Accordingly, even if plasma ions and electrons in the plasma region are moved to pass the exhaust holes 101A of the exhaust ring 101 as shown in FIG. 3B, they are controlled by the action of the magnetic field as shown in FIG. 3C and revolve about the line of magnetic force. Hence, the plasma ions and electrons impinge on the inner periphery of the exhaust holes 101A of the exhaust ring 101, and are confined within the plasma region without leaking out to the non-plasma region.

As explained herein, according to the exhaust ring mechanism of the second embodiment, a magnetic field in the CW direction is formed among plural magnets disposed radially, and plasma and electrons are controlled by the action of the magnetic field to revolve within even if they are moved to pass through the exhaust holes, and impinge on the exhaust holes, and passing is blocked. As a result, the plasma is confined within the plasma region, and the same action and effect as in the first embodiment are obtained.

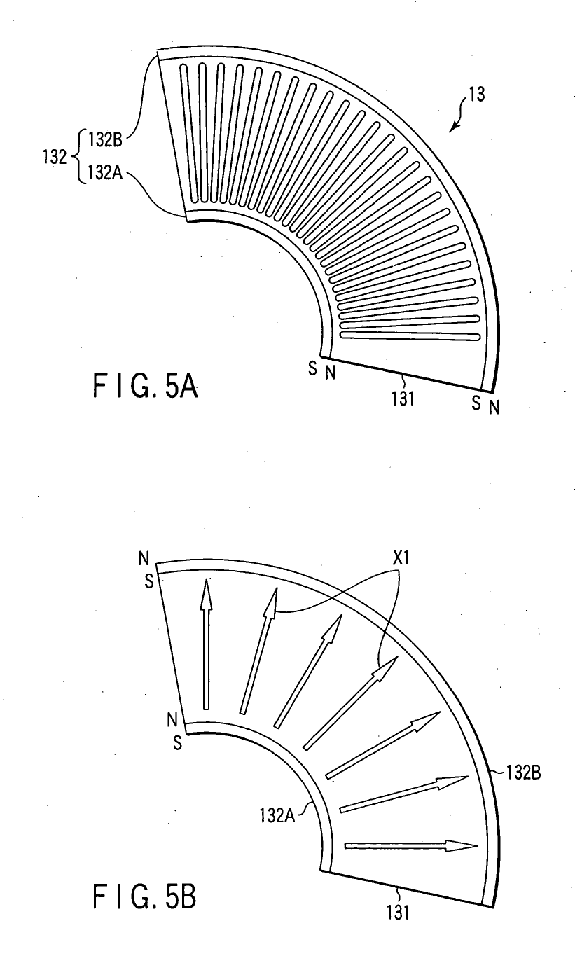

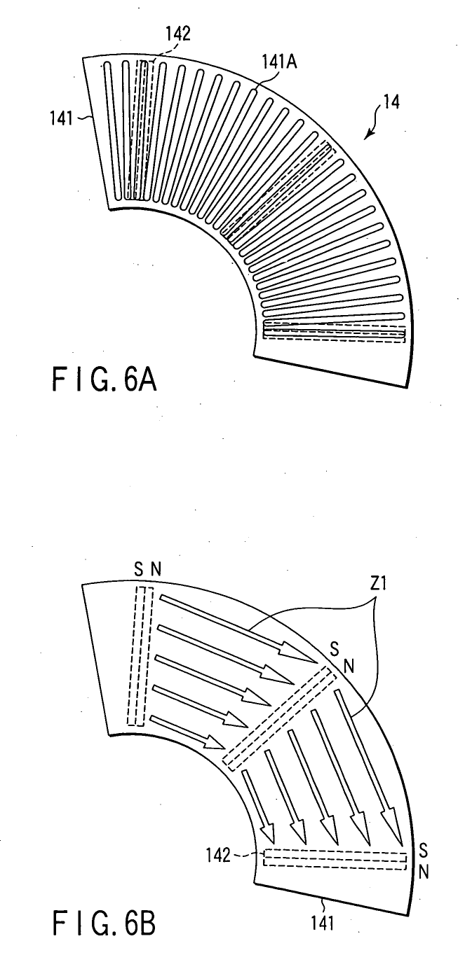

An exhaust ring mechanism for use in a plasma processing apparatus according to a third embodiment of the invention will be described. FIG. 4A is a plan view showing a part of a configuration of the exhaust ring mechanism according to the third embodiment of the invention, and FIG. 4B is a sectional structural view in the radial direction of FIG. 4A.

A magnetic field forming section 112 in the exhaust ring mechanism is composed of first and second ring magnets 112A and 112B same as in the exhaust ring mechanism 7 shown in FIG. 2. However, the exhaust ring mechanism 11 of this embodiment is configured as shown in FIGS. 4A and 4B, in which the first and second ring magnets 112A and 112B are respectively disposed in contact with the inner peripheral edge lower side and outer peripheral edge lower side of an exhaust ring 111.

In this configuration, passing through the exhaust ring 111, a part of the magnetic field going from the first ring magnet 112A toward the second ring magnet 122B is curved and formed in a convex shape. On the whole, this magnetic field is formed as a magnetic field in the horizontal direction crossing the exhaust holes 111A of the exhaust ring 111 nearly horizontally as shown in FIG. 4B.

A line of magnetic force B of this magnetic field is, same as in the foregoing embodiments, substantially orthogonal to the leak direction of plasma ions and electrons. Therefore, even if plasma ions and electrons in the plasma region are moved to pass the exhaust holes 71A of the exhaust ring 71 as shown in FIG. 4B, the plasma ions and electrons are controlled by the action of the magnetic field and revolve about the line of magnetic force, and thereby they are confined within the plasma region without leaking out to the non-plasma region. Hence, also in this embodiment, the same action and effect as in the exhaust ring mechanism 7 shown in FIG. 2A are obtained.

In the foregoing first to third embodiments, nothing is limited, and constituent elements can be freely changed in design as required. For example, the magnetic field forming section is not limited to the first and second ring magnets or magnet plates, but electromagnets having the same shape as those magnets may be used. Instead of the first and second ring magnets, arcuate magnets may be disposed around the exhaust ring. The magnetic field forming section is required only to form a magnetic field parallel to the principal plane direction in the exhaust ring, and the direction of the magnetic field may be any direction as desired.

An exhaust ring mechanism for use in a plasma processing apparatus according to a fourth embodiment of the invention will be described. FIG. 5A is a plan view showing a part of a configuration of the exhaust ring mechanism according to the fourth embodiment of the invention, and FIG. 5B is a diagram showing the direction of a magnetic field vector in the configuration of FIG. 5A.

In the first embodiment shown in FIG. 2, the exhaust holes 71A opened in the exhaust ring 71 of the exhaust ring mechanism are circular, while the fourth embodiment is configured such that exhaust holes formed like slits are disposed radially from the inner side to the outer periphery.

This exhaust ring mechanism 13 is composed of an exhaust ring 131 and a magnetic field forming section 132. The magnetic field forming section 132 is composed of a first ring magnet 132A covering the inner periphery of the exhaust ring 131, and a second ring magnet 132B covering the outer periphery of the exhaust ring 131 as shown in FIG. 5A.

In this configuration, as shown in FIG. 5B, the magnetic field forming section 132 forms a magnetic field in the direction X1 parallel to the principal plane toward the inner wall of the processing chamber 1 from the lower electrode 2 shown in FIG. 1. This magnetic field confines the generated plasma within the plasma region and prevents leak of the plasma into the non-plasma region.

In this embodiment, the same action and effect as in the first embodiment can be obtained.

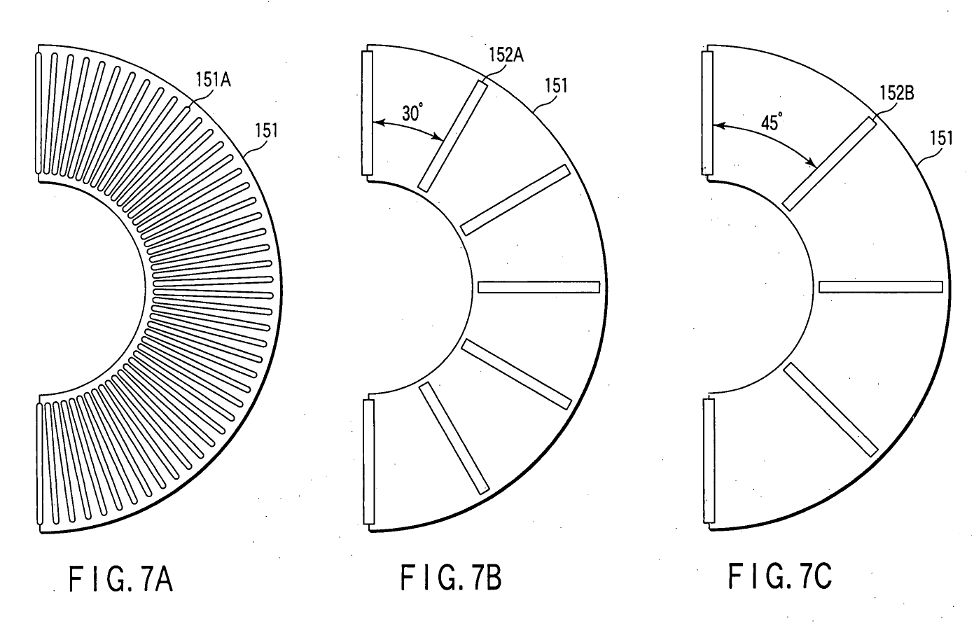

An exhaust ring mechanism for use in a plasma processing apparatus according to a fifth embodiment of the invention will be described. FIG. 6A is a partial plane view showing a plane configuration of the exhaust ring mechanism according to the fifth embodiment of the invention, and FIG. 6B is a diagram showing the direction of a magnetic field vector in the configuration of FIG. 6A.

The exhaust ring mechanism 14 for use in this plasma processing apparatus is composed of an exhaust ring 141 and a magnetic field forming section 142 as shown in FIGS. 6A and 6B. The magnetic field forming section 142 is composed of a plurality of magnets 142A disposed radially at a predetermined interval in the peripheral direction of the exhaust ring 141. Each magnet 142A is formed like a plate, and is provided to fill in exhaust holes 141A formed like slits in the exhaust ring 141. Between mutually adjacent magnets 142A of the exhaust ring 141, a magnetic field is formed in a clockwise rotating direction (CW) as indicated by arrow Z1 in FIG. 6B.

According to the embodiment, the same action and effect as in the second embodiment are obtained in addition to the same action and effect as in the first embodiment.

An exhaust ring mechanism for use in a plasma processing apparatus according to a sixth embodiment of the invention will be described. FIG. 7A is a partial plane view showing a plane configuration of the exhaust ring mechanism according to the sixth embodiment of the invention, FIG. 7B is a diagram of a first example of magnet layout, and FIG. 7C is a diagram of a second example of magnet layout.

The exhaust ring mechanism of this embodiment is composed of an exhaust ring 151 and a plurality of magnets 152A of a magnetic field forming section, or exhaust ring 151 and magnets 152B. In the exhaust ring 151, same as the exhaust ring in the above-described fourth embodiment, exhaust holes 151A formed like slits are radially disposed from the inner side to the outer periphery.

As shown in FIG. 7B, as a first layout example, the magnets 152A for forming a magnetic field are disposed radially at an interval of angle of 30 degrees each in the peripheral direction of the exhaust ring 151. The magnets 152A are formed like plates, and arrayed and fitted at the lower side of the exhaust ring 151.

As shown in FIG. 7C, as a second layout example, the magnets 152B for forming a magnetic field are disposed radially at an interval of angle of 45 degrees each in the peripheral direction of the exhaust ring 151. These magnets 152A, 152B are formed like plates, and arrayed and fitted at the lower side of the exhaust ring 151. In the first and second layout examples, between the adjacent magnets 152A or between the magnets 152B, a magnetic field is formed in a clockwise rotating direction (CW) as indicated by arrow Z1 in FIG. 6B.

According to this embodiment, the same action and effect as in the second embodiment are obtained.

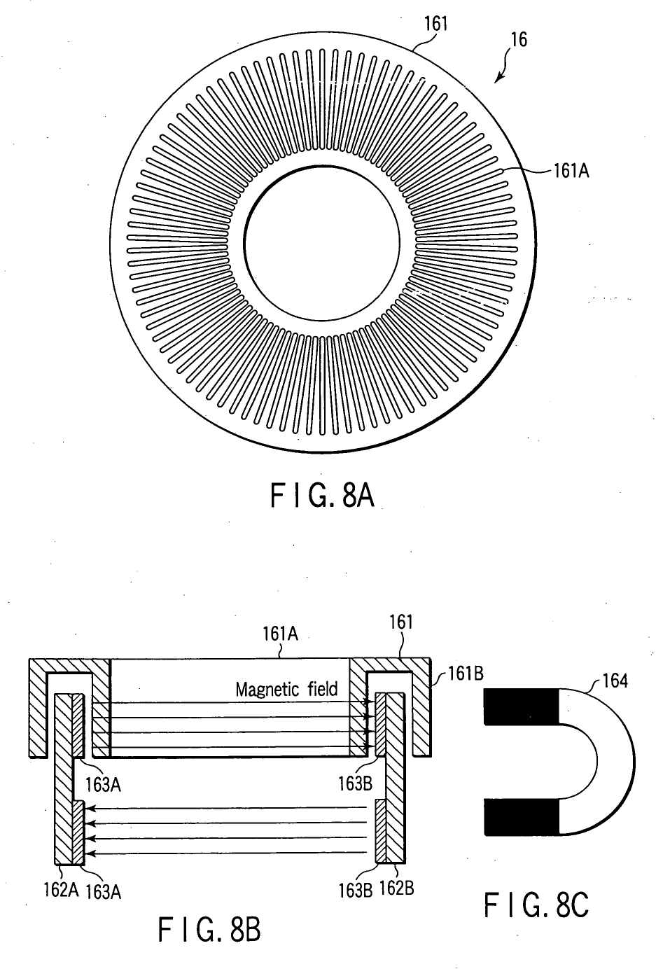

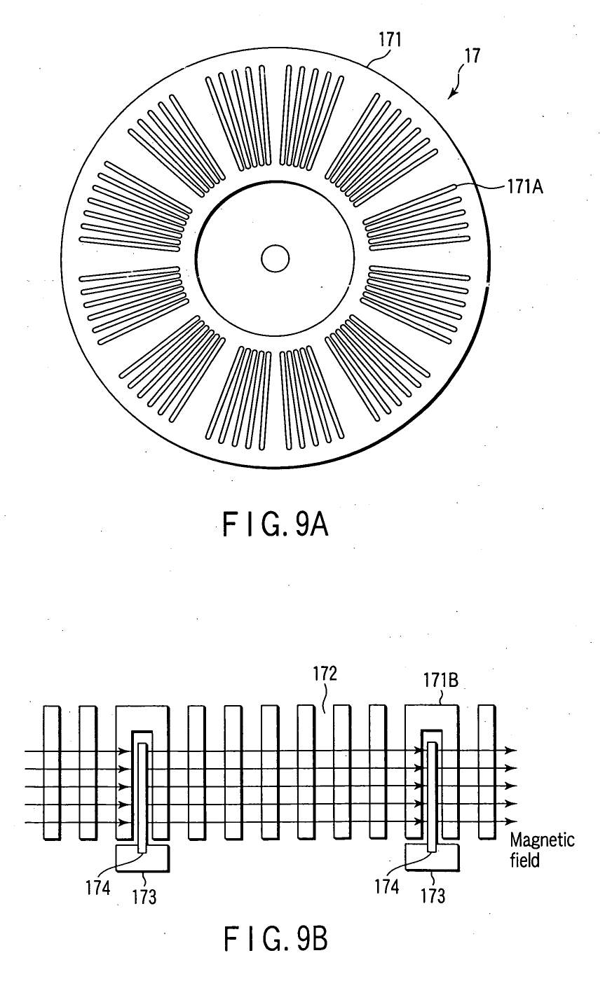

An exhaust ring mechanism for use in a plasma processing apparatus according to a seventh embodiment of the invention will be described. FIG. 8A is a plane configuration view as seen from above an exhaust ring of the exhaust ring mechanism according to the seventh embodiment of the invention, FIG. 8B is a diagram showing an example of magnet layout and the direction of a magnetic field vector in the configuration of FIG. 8A, and FIG. 8C is a diagram explaining the concept of formation of a magnetic field in the embodiment.

In the foregoing first to sixth embodiments, the magnets are disposed directly at the lower side of the exhaust ring, and the process gas passing through the exhaust holes is designed to run on the surface of the magnets. When the processing apparatus is an etching apparatus or the like, a corrosive gas is used as the process gas, and the magnets may be corroded by the corrosive gas at the time of exhaust.

This embodiment is configured so that the exhaust passage of the exhaust gas (corrosive gas) may not contact directly with the magnets. As shown in FIG. 8A, the exhaust ring 161 has exhaust holes 161A in slit forms disposed radially from the inner side to the outer periphery over the entire periphery.

As shown in FIG. 8B, an inner peripheral side magnet base member 162A and an outer peripheral side magnet base member 163B of ring shape made of conductors are fitted into an exhaust ring cover 161B provided at the lower end of the inner and outer periphery of the exhaust ring 161.

Upper and lower ring magnets 163A are provided at the outer and inner side of the magnet base member 162A, and upper and lower ring magnets 163B are provided at the inner side of the magnet base member 162B. At this time, the ring magnets 163A and ring magnets 163B are disposed so as to be opposite to the N pole and S pole, respectively, and thereby a magnetic field is formed in the principal plane direction (direction parallel to the principal plane) of the exhaust ring 161. Conceptually, it is equivalent to that two U-shaped magnets are arranged so as to opposite to the N pole and S pole as shown in FIG. 8C. This magnetic field functions to confine the generated plasma within the plasma region and prevent leak of the plasma to the non-plasma region.

According to this embodiment, since the exhaust passage of exhaust gas (corrosive gas) does not directly contact with the magnet, corrosion of magnets can be prevented. In addition, by the formed magnetic field, the generated plasma is confined within the plasma region, and leak of the plasma to the non-plasma region can be prevented. Hence, the same action and effect as in the first embodiment are obtained.

An exhaust ring mechanism for use in a plasma processing apparatus according to an eighth embodiment of the invention will be described. FIG. 9A is a plane configuration view as seen from above an exhaust ring of the exhaust ring mechanism according to the eighth embodiment of the invention, and FIG. 9B is a diagram showing an example of magnet layout and the direction of a magnetic field vector in the configuration of FIG. 9A.

In this embodiment, as shown in FIG. 9A, the exhaust ring 171 has a plurality of exhaust holes 171A formed like slits radially from the inner side to the outer periphery over the entire periphery, in groups of the exhaust holes 171A, and a space 171B is disposed between groups. In the layout example in FIG. 9A, five to seven exhaust holes 171A compose one group. Such layout may be freely changed depending on the design and configuration of exhaust efficiency and the like.

As shown in FIG. 9B, the magnetic field forming section has plate magnets 174 provided on a magnet base member 173 made of conductor. The lower side of the space 171B of the magnet ring 171 mentioned above accommodates the magnets 173, and it is formed in a concave shape so as to cover the entire magnet. By putting the magnets 173 in the space 171B, the exhaust passage of the exhaust gas (corrosive gas) does not directly contact with the magnets.

According to the embodiment, same as in the foregoing seventh embodiment, corrosion of magnets by the exhaust of corrosive gas can be prevented. In addition, by the formed magnetic field, the generated plasma is confined within the plasma region, and leak of the plasma to the non-plasma region can be prevented. Hence, the same action and effect as in the first embodiment are obtained.

An exhaust ring mechanism for use in a plasma processing apparatus according to a ninth embodiment of the invention will be described.

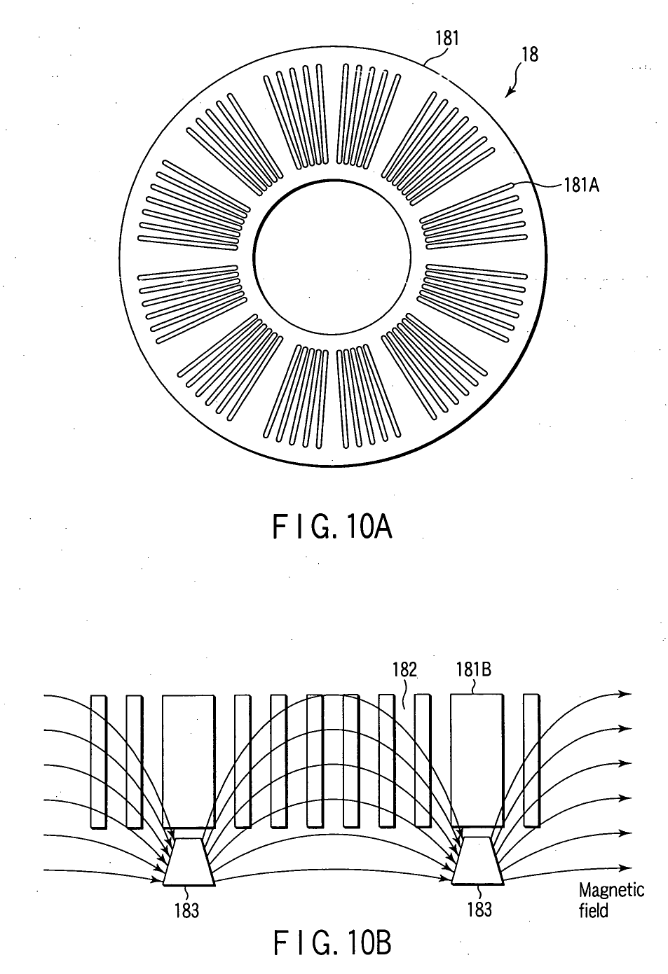

FIG. 10A is a plane configuration view as seen from above an exhaust ring of the exhaust ring mechanism according to the ninth embodiment of the invention, and FIG. 10B is a diagram showing an example of magnet layout and the direction of a magnetic field vector in the configuration of FIG. 10A.

The exhaust ring 181 in the exhaust ring mechanism shown in FIG. 10A has exhaust holes 181A of slit form disposed same as in the eighth embodiment. A magnetic field forming section in the exhaust ring mechanism is as shown in FIG. 10B, in which magnets 183 (permanent magnets or electromagnets) are disposed at the lower side of each space 181B provided between groups of the exhaust holes 181A.

In this configuration, the magnet 183 is formed in a tapered shape like trapezoidal form, and the magnetic field is formed so that a line of magnetic force may pass from the magnet 183 to a next magnet 183 within the exhaust ring 181 to be curved in a convex profile. By this magnetic field, same as in the foregoing embodiments, even if plasma ions and electrons in the plasma region are moved to pass the exhaust holes 182, they are controlled by the action of the magnetic field and revolve, and are confined within the plasma region without leaking out to the non-plasma region.

Since the magnets 183 are disposed behind (in the non-plasma region of) the space 181B, the exhaust passage of the exhaust gas (corrosive gas) does not contact directly with the magnet.

According to the embodiment, same as in the seventh embodiment, corrosion of magnet by exhaust corrosive gas can be prevented. In addition, the generated plasma can be confined within the plasma region by the generated magnetic field, and leak of the plasma into the non-magnetic plasma region can be prevented. The same action and effect as in the first embodiment can be obtained.

A configuration in which a function of an exhaust ring mechanism for use in a plasma processing apparatus according to a tenth embodiment of the invention is applied to a deposit shield mechanism will be described.

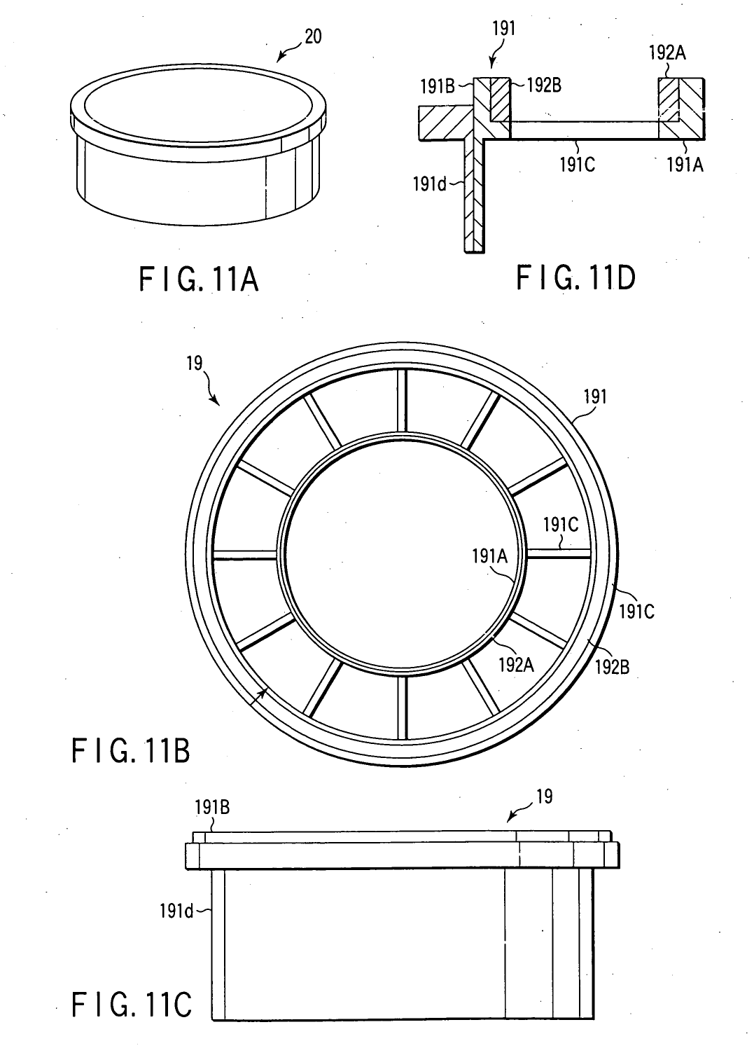

FIG. 11A is a view showing an outer appearance of the deposit shield mechanism to which the function of the exhaust ring mechanism in the respective embodiments is applied, FIG. 11B is a top view showing a plane configuration of the deposit shield in FIG. 11A, FIG. 11C is a side view showing an appearance configuration of the deposit shield in FIG. 11A, and FIG. 11D is a partial sectional view showing a configuration of magnets arranged in the radial direction in the deposit shield.

In the foregoing embodiments, the exhaust ring mechanism incorporating the magnetic field by magnets in the exhaust ring is explained, but this embodiment is intended to form the magnetic field in the deposit shield in order to cover this magnetic field in the processing chamber around the lower electrode. In this example, since a processing chamber with a circular inside is assumed, it is a tubular form, but the shape is not particularly limited.

The deposit shield 19 is formed of a conductive material such as aluminum, and an outer ring member 191B and an inner ring member 191A supported by a plurality of ring supports 191C are provided on its upper part. When the inner ring member 191A is provided in the processing chamber, it is fitted into the lower electrode, and is formed to a height so as to be same as or slightly lower than the platform of the lower electrode.

A pair of ring magnets 192A and 192B are provided so as to be opposite to the N pole and S pole, at an inner wall side of the outer ring member 191B and an outer wall side of the inner ring member 191A.

By these magnets 192A and 192B (permanent magnets or electromagnets), a magnetic field is formed in the same radial direction as shown in FIG. 5B, the generated plasma is confined in the plasma region, and leak of the plasma to the non-plasma region can be prevented. In this embodiment, if the apparatus is composed so that the magnetic field cannot be formed in the exhaust ring unlike the first to ninth embodiments, plasma leak can be prevented by providing the deposit shield disposed around the lower electrode with the magnetic field forming function.

A configuration in which a function of an exhaust ring mechanism for use in a plasma processing apparatus according to an eleventh embodiment of the invention is applied to a deposit shield mechanism will be described.

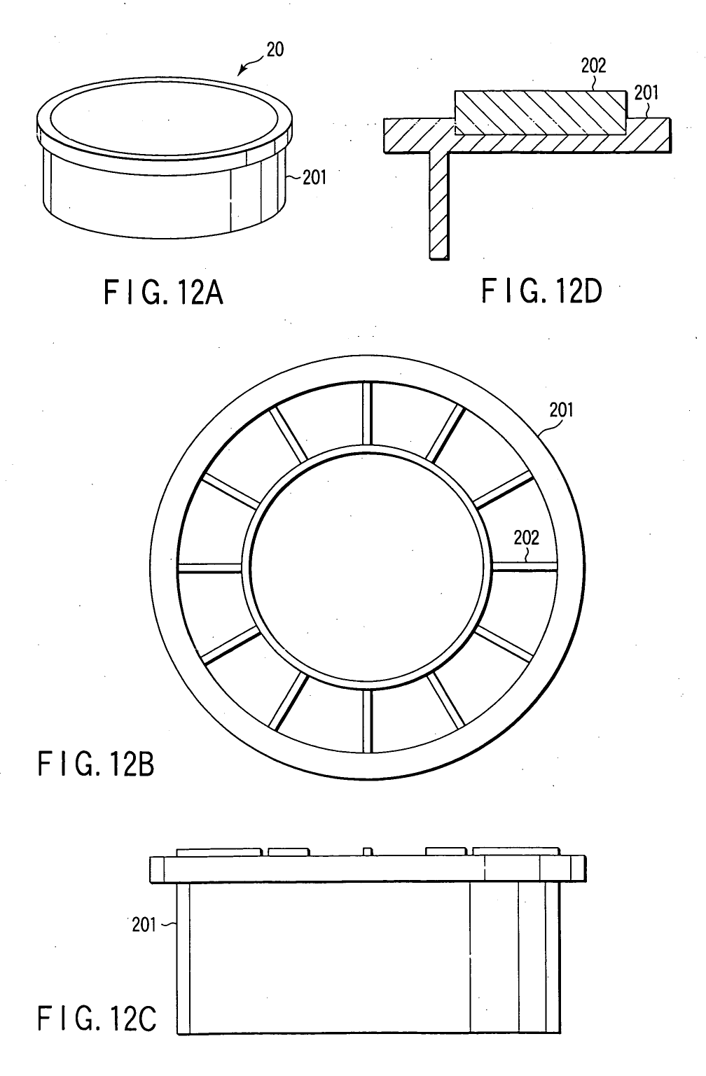

FIG. 12A is a view showing an outer appearance of a deposit shield mechanism to which the function of the exhaust ring mechanism in the embodiments is applied, FIG. 12B is a top view showing a plane configuration of the deposit shield in FIG. 12A, FIG. 12C is a side view showing an appearance configuration of the deposit shield in FIG. 12A, and FIG. 12D is a partial sectional view of a configuration of magnets arranged in the peripheral direction in the deposit shield.

In the foregoing tenth embodiment, the magnetic field in the radial direction is formed by disposing ring magnets oppositely in the radial direction, while magnets are disposed in the peripheral direction in this embodiment, and a magnetic field is formed in the peripheral direction (CW direction). Also in this example, since a processing chamber with a cylindrical inside is assumed, it is a tubular form, but the shape is not particularly limited.

The deposit shield 20 is formed of a conductive material such as aluminum, and, same as in the tenth embodiment, an outer ring member and an inner ring member supported by a plurality of ring supports are provided on its upper part. When the inner ring member is provided in the processing chamber, it is fitted into the lower electrode, and is formed to a height so as to be same as or slightly lower than the platform of the lower electrode.

Plate magnets 202 are provided on these ring supports.

By these magnets 202, a magnetic field is formed in the same peripheral direction as shown in FIG. 3A, the generated plasma is confined in the plasma region, and leak of the plasma to the non-plasma region can be prevented. In this embodiment, if the apparatus is composed so that the magnetic field cannot be formed in the exhaust ring unlike the first to ninth embodiments, plasma leak can be prevented by providing the deposit shield disposed around the lower electrode with the magnetic field forming function.

The magnets in the foregoing embodiments may be realized by permanent magnets or electromagnets.

Further, the magnets, electromagnets and magnetic container may be coated by putting, for example, in an aluminum case with alumite treated surface so as not to spoil the original function due to fluctuation of the magnetic field by temperature rise due to impingement of plasma ions, electrons or the like. The exhaust ring has exhaust holes of circular or slit shape, but not limited to these examples, exhaust holes may be formed freely such as elliptical or rhombic shape.

In the foregoing embodiments, the plasma processing apparatus of parallel flat plate type is explained, but the exhaust ring mechanism and deposit shield mechanism of the invention may be applied in a plasma processing apparatus of any type of exhausting gas through an exhaust ring.

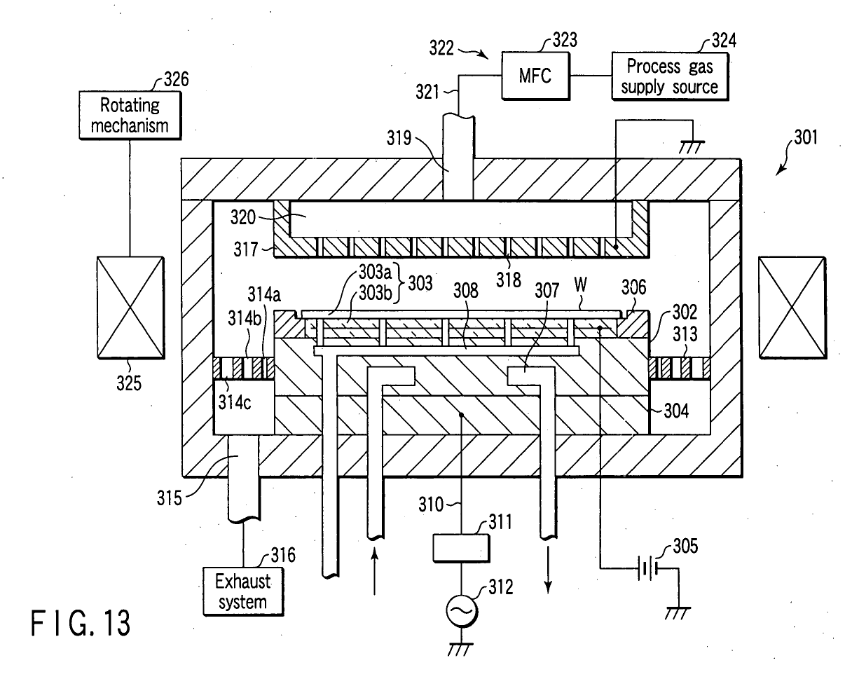

FIG. 13 is a general schematic diagram showing a configuration of a vacuum processing apparatus (plasma processing apparatus, plasma etching apparatus) according to the tenth embodiment of the invention.

A cylindrical processing chamber 301 is made of aluminum of which surface is treated with an anodic oxidation coat film (alumite), and an airtight closed vacuum processing chamber (plasma processing chamber) is composed.

The processing chamber 301 is connected to a grounding potential. Inside of this processing chamber 301, there is a platform (susceptor) 302 serving also as a lower electrode, the platform being composed in a disk form made of aluminum or the like having an anodic oxidation coat film (alumite) formed thereon.

On a semiconductor wafer W mounting surface of this platform 302, an electrostatic chuck 303 is provided. This electrostatic chuck 303 is an integral structure of an insulating film 303b made of an insulating material such as polyimide with an electrostatic chuck electrode 303a sealed therein.

The platform 302 is supported in the vacuum chamber 301 by way of an insulating plate 304 of ceramics or the like, and a direct-current power source 5 is connected to the electrostatic chuck electrode 303a of the electrostatic chuck 303. A focus ring 306 is provided also on the platform 302 in an annular form so as to surround the semiconductor wafer W.

Inside of the platform 302, there are provided a heat medium passage 307 for circulating an insulating fluid as a heat medium for temperature control, and a gas passage 308 for supplying temperature control gas such as helium gas to the back side of the semiconductor wafer W.

The platform 302 is controlled at a predetermined temperature by circulating the insulating fluid controlled at a predetermined temperature in the heat medium passage 307. In addition, temperature control gas is supplied between the platform 302 and the back side of the semiconductor wafer W through the gas passage 308, and heat exchange between the two is promoted, so that the semiconductor wafer W can be controlled at the predetermined temperature precisely and efficiently.

Substantially in the center of the platform 302, a feeder wire 310 is connected for supplying high frequency electric power. A radio frequency power source (RF power source) 312 is connected to the feeder wire 310 by way of a matching device 311. The RF power source 312 supplies a high frequency electric power of a predetermined frequency.

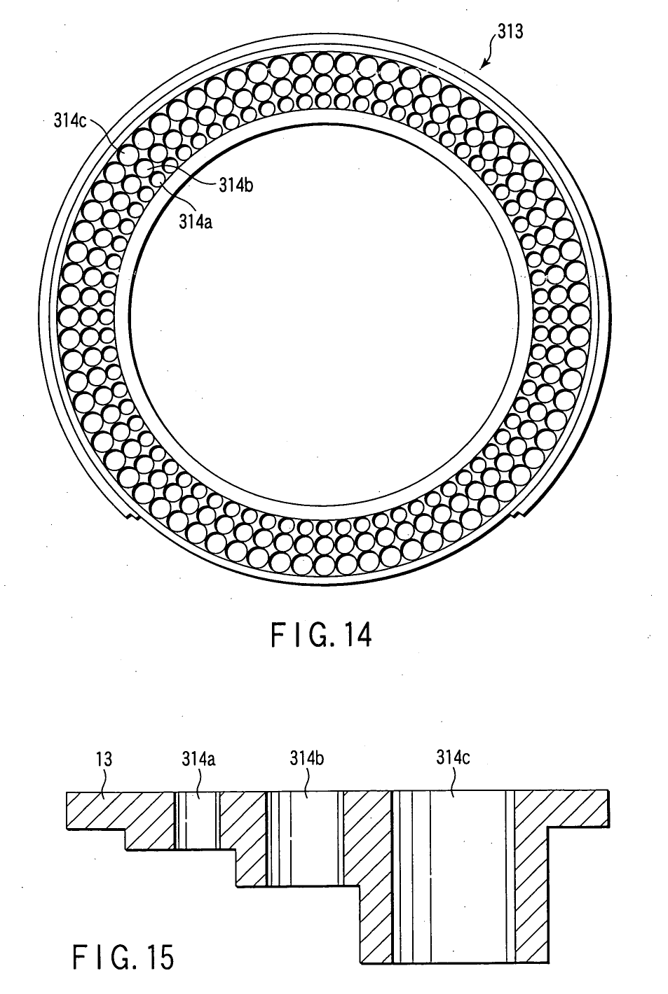

Outside of the focus ring 306, an annular exhaust ring 313 of an exhaust ring mechanism is provided. This exhaust ring 313 has plural types (three types in this embodiment) of exhaust holes 314a, 314b, 314c differing in the opening area as shown in FIG. 14. These exhaust holes 314a, 314b, 314c are arranged such that the opening area increases gradually from the inner side to the outer side in the sequence of the exhaust holes 314a provided at the inner side of the exhaust ring 313, the exhaust holes 314b provided in the middle, and the exhaust holes 314c provided at the outermost side. In this embodiment, the exhaust holes 314a, 314b, 314c are circular holes, and the size of the opening area is equal to the size of the diameter of circular holes.

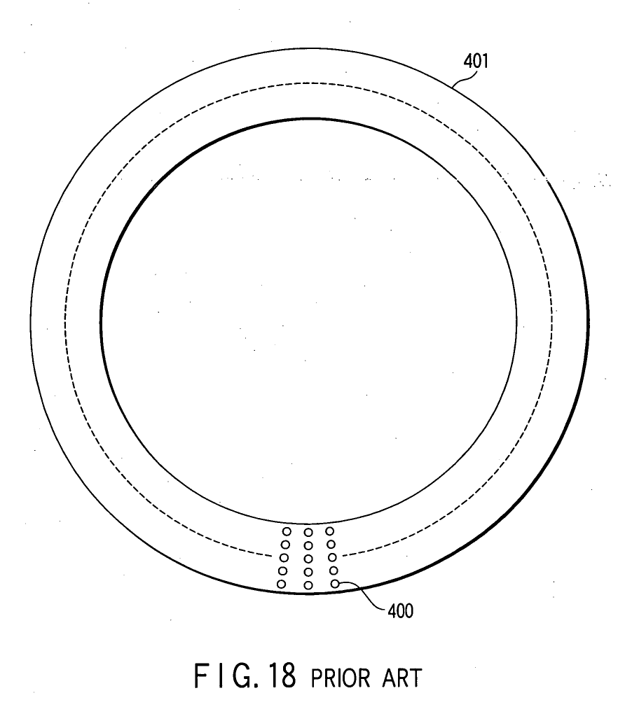

As described above, the exhaust ring 313 has plural types of exhaust holes 314a, 314b, 314c differing in the opening area arranged in the sequence of gradual increase of the opening area (diameter of circular hole) from the inner side to the outer side, and therefore the space among the exhaust holes can be utilized effectively as compared with the conventional exhaust ring 401 shown in FIG. 18 in which exhaust holes 400 of the same opening area, that is, the same diameter are arranged.

In FIG. 18, when the exhaust holes 400 of the same diameter are arranged linearly in the radial direction, the interval between the adjacent exhaust holes 400 ion the radial direction is wider at the outer side, and an ineffective space (dead space) increases from the viewpoint of exhaust efficiency.

By contrast, as shown in FIG. 14, if the exhaust holes 314a, 314b, 314c of different opening area are arranged such that the opening area (diameter of circular hole) increases gradually from the inner side to the outer side, the interval of the adjacent exhaust holes 314c and 314c in the radial direction is not broadened at the outer side, and the space on the exhaust ring 313 may be utilized effectively.

As a result, the opening area of the entire exhaust ring 313 can be increased, and the conductance of the entire exhaust ring 313 can be increased, so that the exhaust efficiency may be enhanced. As the diameter of the exhaust holes 314a, 314b, 314c is increased, the conductance can be increased, but if the diameter of the exhaust holes 314a, 314b, 314c is too large, possibility of leak of the plasma beneath the exhaust ring 313 increases. Such plasma leak can be prevented by slightly increasing the plate thickness of the exhaust ring 313, but when the plate thickness of the exhaust ring 313 is increased, the conductance is lowered.

By varying the diameter of the exhaust holes 314a, 314b, 314c and plate thickness of the exhaust ring 313, the relation between the conductance and the plasma leak preventive effect was studied by calculation. As a result, it is found that the size of the exhaust holes 314a, 314b, 314c is preferably set at 5 to 20 mm in the diameter of the exhaust holes 314c having the largest opening area at the outermost side. In this case, if the plate thickness of the exhaust ring 313 is too thin, as mentioned above, possibility of leak of the plasma beneath the exhaust ring 313 through the exhaust holes 314c or the like is increased.

Accordingly, the plate thickness of the exhaust ring 13 is preferred to be about 5 to 20 mm. For example, when the diameter of the exhaust holes 314c having the largest opening area at the outermost side is set at 10 mm and the plate thickness of the exhaust ring 313 is 15 mm, the conductance is at least two times higher than in the exhaust ring 401 (diameter of the exhaust holes 400 is 1.5 mm and plate thickness is 2 mm) shown in FIG. 18, and also the plasma leak preventive effect can be also improved.

Since the opening area of the exhaust holes 314a, 314b, 314c is different, the plate thickness of the exhaust ring 313 required to prevent plasma leak is also different for each one of the exhaust holes 314a, 314b, 314c. That is, for example, in the exhaust holes 314a of a relatively small opening area, the plate thickness of the exhaust ring 13 required to prevent plasma leak is smaller than in the exhaust holes 314c of large opening area.

Accordingly, as shown in FIG. 15, the plate thickness of the exhaust ring 313 is changed in steps such that the thickness is appropriate in the respective exhaust holes 314a, 314b, 314c. In such a configuration, while preventing plasma leak, the conductance of the exhaust ring 313 may be further enhanced and the exhaust efficiency can be improved.

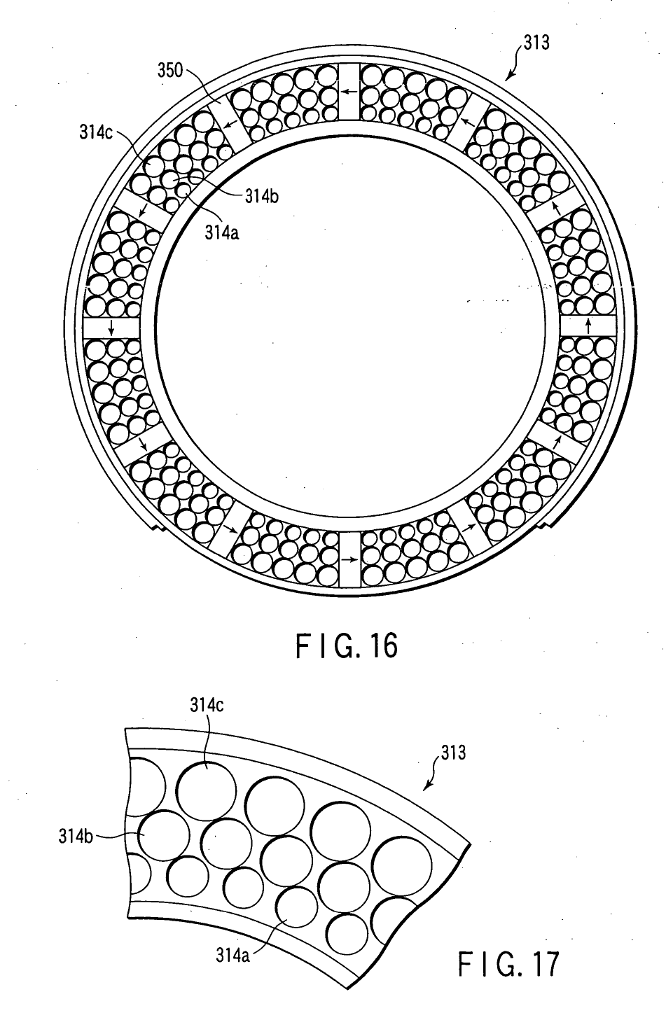

An exhaust ring mechanism for preventing plasma leak has an exhaust ring 313 and magnets 350 (12 magnets in FIG. 16), as shown in FIG. 16. The magnets 350 are provided on the ring 313 and spaced at a predetermined interval (an interval of 30 degrees in the example in FIG. 16) in the exhaust ring 313. It is also effective to form a magnetic field near the exhaust ring 313. As the direction of the magnetic pole is indicated by arrow in FIG. 16, the magnetic poles of the magnets 350 are arranged along the peripheral direction of the exhaust ring 313.

By forming a magnetic field near the exhaust ring 313, the trajectory of charged particles in the plasma can be bent to as to impinge on the inner wall of the exhaust ring 313 in the exhaust holes 314a, 314b, 314c, and thereby leak of the plasma can be prevented.

In the exhaust ring mechanism of this configuration, as shown in FIG. 16, the number of the exhaust holes 314a, 314b, 314c that can be formed in the exhaust ring 313 is decreased because the space for installing the magnets 350 is needed as compared with the case not forming the magnets 350.

However, when the magnets 350 are formed, the plate thickness of the exhaust ring 313 required to prevent plasma leak is thinner than in the case not forming the magnets 350. On the whole, as compared with the case not forming the magnets 350, the conductance of the exhaust ring 313 can be enhanced and the exhaust efficiency can be improved.

In the exhaust ring 313 shown in FIGS. 14 and 16, the exhaust holes 314a, 314b, 314c are arranged linearly along the radial direction, but by shifting the exhaust holes 314a, 314b, 314c in the peripheral direction as shown in FIG. 17, they may be arranged in a zigzag form instead of linear form. In such a configuration, an ineffective space (dead space) on the exhaust ring 313 can be decreased.

Although, in the exhaust ring 313 shown in FIGS. 14, 16, and 17, the exhaust holes 314a, 314b, 314c are formed in circular holes, the shape of the exhaust holes 314a, 314b, 314c is not limited to a circular form, but may be formed in polygonal or any other shape.

An exhaust port 315 is provided beneath the exhaust ring 313, and by a vacuum pump or the like of an exhaust system 316 connected to this exhaust port 315, the processing space in the processing chamber 301 is evacuated to a vacuum space by way of the exhaust ring 313.

On the other hand, in the top wall of the processing chamber 301 above the platform 2, a shower head 317 is provided parallel to the platform 2, and this shower head 317 is grounded. Therefore, the platform 302 and shower head 317 are designed to function as a pair of electrodes (upper electrode and lower electrode).

The shower head 317 has a multiplicity of gas discharge holes 318 at its lower side, and a gas feed section 319 is provided at its upper side. A gas diffusion gap 320 is formed inside the shower head. A gas supply piping 321 is connected to the gas feed section 319, and a gas supply system 322 is connected to the other end of this gas supply piping 321. The gas supply system 322 is composed of a mass flow controller (MFC) 323 for controlling the gas flow rate, a process gas supply source 324 for supplying process gas for etching or the like, and others.

On the outer periphery of the processing chamber 301, an annular magnetic field forming mechanism (ring magnet) 325 is disposed concentrically with the processing chamber 301, and a magnetic field is formed in the processing space between the platform 302 and the shower head 317. This magnetic field forming mechanism 325 can be rotated by a rotating mechanism 326 at a predetermined speed around the processing chamber 301.

Plasma etching procedure by the plasma etching device having such a configuration will be explained below.

A gate valve (not shown) provided in the processing chamber 301 is opened, and the semiconductor wafer W is delivered into the processing chamber 301 by a-conveying mechanism (not shown) through a load lock chamber (not shown) disposed adjacently to the gate valve, and is put on the platform 302.

After moving the conveying mechanism away from the processing chamber 301, the gate valve is closed. By applying a predetermined direct-current voltage from the direct-current power source 305 to the electrostatic chuck electrode 303a of the electrostatic chuck 303, the semiconductor wafer W is attracted and held.

Consequently, operating the vacuum pump of the exhaust system 316, the processing space in the processing chamber 301 is evacuated to a predetermined degree of vacuum, for example, 1.33 Pa to 133 Pa by way of the exhaust ring 313, while a predetermined processing gas is supplied into the processing chamber 301 from the processing gas supply system 322.

In this state, a high frequency of a predetermined frequency, for example, tens of MHz to over hundred MHz is applied to the platform 302 from the RF power source 312 by way of the matching device 311, a plasma is generated in the space between the platform 302 and the shower head 317, the semiconductor wafer W is etched by the plasma.

During this etching process, by exhausting the processing space in the processing chamber 301 through the exhaust ring 313, the surrounding of the semiconductor wafer W mounted on the platform 302 is uniformly exhausted, and a uniform flow of processing gas is formed around the semiconductor wafer W, so that processing of high in-plane uniformity is applied on the whole surface of the semiconductor wafer W. Besides, since the conductance of the exhaust ring 313 is high, the exhaust efficiency is enhanced, and favorable processing can be conducted at a desired degree of vacuum, while plasma leak can be prevented.

When predetermined etching process for the semiconductor wafer W is terminated, by stopping supply of high frequency electric power from the RF power source 312, plasma etching process is stopped, and the semiconductor wafer W is discharged from the processing chamber 301 in the reverse procedure of the above operation.

In this embodiment, the invention is applied to the plasma etching apparatus for processing the semiconductor wafer W by plasma etching. However, the invention is not limited to the illustrated embodiments alone, but may be applied in film forming apparatus, or any other vacuum processing apparatus. The substrate to be processed is not limited to the semiconductor wafer W, but it can be similarly applied in vacuum processing of LCD board and the like.

As described herein, according to the plasma processing apparatus and exhaust ring mechanism of the invention, as compared with the prior art, the conductance of the exhaust ring can be enhanced and the exhaust efficiency can be also improved.

What is claimed is:

1. An exhaust ring mechanism that contacts with a plasma region to subject an object to be processed to plasma processing in a processing chamber and provides an exhaust passage for process gas in the plasma region, the exhaust ring mechanism comprising:
an exhaust ring having a surface contacting with the plasma region; and
a magnetic field forming section which forms a magnetic field having a line of magnetic force, substantially parallel to the direction of the surface of the exhaust ring.

2. The exhaust ring mechanism according to claim 1, wherein the magnetic field forming section is formed so that at least part of the line of magnetic force passes the inside of the exhaust ring.

3. The exhaust ring mechanism according to claim 1, wherein the magnetic field forming section is configured of a plurality of magnets or electromagnets disposed along an inner periphery and an outer periphery on the surface of the exhaust ring.

4. The exhaust ring mechanism according to claim 2, wherein the magnetic field forming section is configured of magnets or electromagnets disposed along an inner periphery and an outer periphery on the surface of the exhaust ring.

5. The exhaust ring mechanism according to claim 1, wherein the magnetic field forming section is configured of a plurality of magnets or electromagnets disposed along an inner peripheral edge and an outer peripheral edge on the lower surface of the exhaust ring.

6. The exhaust ring mechanism according to claim 2, wherein the magnetic field forming section is configured of a plurality of magnets or electromagnets disposed along an inner peripheral edge and an outer peripheral edge on the lower surface of the exhaust ring.

7. The exhaust ring mechanism according to claim 1, wherein the magnetic field forming section is configured of a plurality of magnets or a plurality of electromagnets disposed radially at a predetermined interval in the peripheral direction in the exhaust ring.

8. The exhaust ring mechanism according to claim 2, wherein the magnetic field forming section is configured of a plurality of magnets or a plurality of electromagnets disposed radially at a predetermined interval in the peripheral direction in the exhaust ring.

9. The exhaust ring mechanism according to claim 1, wherein the magnetic field forming section is configured of a plurality of magnets or a plurality of electromagnets disposed radially at a predetermined interval in the peripheral direction at the lower surface side of the exhaust ring.

10. The exhaust ring mechanism according to claim 2, wherein the magnetic field forming section is configured of a plurality of magnets or a plurality of electromagnets disposed radially at a predetermined interval in the peripheral direction at the lower surface side of the exhaust ring.

11. The exhaust ring mechanism according to claim 1, wherein the exhaust ring mechanism has a magnetic field sealing section.

12. The exhaust ring mechanism according to claim 11, wherein the magnetic field sealing section is composed of a magnetic element.

13. A plasma processing apparatus for processing an object to be processed by plasma, comprising:
a holder which is disposed in a processing chamber and holds the object to be processed; and
an exhaust ring mechanism disposed between the holder and the processing chamber and having:
exhaust holes,
an exhaust ring having a surface contacting with the plasma region; and
a magnetic field forming section which forms a magnetic field having a line of magnetic force substantially parallel to the direction of the surface of the exhaust ring.

14. The plasma processing apparatus according to claim 13, wherein the magnetic field forming section is formed so that at least part of the line of magnetic force passes the inside of the exhaust ring.

15. The plasma processing apparatus according to claim 13, wherein the magnetic field forming section is configured of a plurality of magnets or electromagnets disposed along an inner periphery and an outer periphery on the surface of the exhaust ring.

16. The plasma processing apparatus according to claim 14, wherein the magnetic field forming section is configured of a plurality of magnets or electromagnets disposed along an inner periphery and an outer periphery on the surface of the exhaust ring.

17. The plasma processing apparatus according to claim 13, wherein the magnetic field forming section is configured of a plurality of magnets or electromagnets disposed along an inner peripheral edge and an outer peripheral edge on the lower surface of the exhaust ring.

18. The plasma processing apparatus according to claim 14, wherein the magnetic field forming section is configured of a plurality of magnets or electromagnets disposed along an inner peripheral edge and an outer peripheral edge on the lower surface of the exhaust ring.

19. The plasma processing apparatus according to claim 13, wherein the magnetic field forming section is configured of a plurality of magnets or a plurality of electromagnets disposed radially at a predetermined interval in the peripheral direction in the exhaust ring.

20. The plasma processing apparatus according to claim 14, wherein the magnetic field forming section is configured of a plurality of magnets or a plurality of electromagnets disposed radially at a predetermined interval in the peripheral direction in the exhaust ring.

21. The plasma processing apparatus according to claim 13, wherein the magnetic field forming section is configured of a plurality of magnets or a plurality of electromagnets disposed radially at a predetermined interval in the peripheral direction in the exhaust ring.

22. The plasma processing apparatus according to claim 14, wherein the magnetic field forming section is configured of a plurality of magnets or a plurality of electromagnets disposed radially at a predetermined interval in the peripheral direction at the lower surface side of the exhaust ring.

23. The plasma processing apparatus according to claim 13, wherein the exhaust ring mechanism has a magnetic field sealing section.

24. The plasma processing apparatus according to claim 23, wherein the magnetic field sealing section is composed of a magnetic element.

25. A deposit shield mechanism that is in a processing chamber to protect an inner wall of the processing chamber and is in contact with a plasma region where an object to be processed is subjected to plasma processing and with an exhaust passage of process gas in the plasma region, the deposit shield mechanism comprising:
a magnetic field forming section which forms, at the end that is in contact with the plasma region, a magnetic field having a line of magnetic force substantially parallel to the direction of an electrode surface which forms the plasma.

26. The deposit shield mechanism according to claim 25, wherein the magnetic field forming section is formed so that at least part of the line of magnetic force passes the upper part of the deposit shield.

27. The deposit shield mechanism according to claim 25, wherein the magnetic field forming section is configured of a plurality of magnets or a plurality of electromagnets disposed along an inner periphery and an outer peripheral edge provided in the upper part of the deposit shield.

28. The deposit shield mechanism according to claim 26, wherein the magnetic field forming section is configured of a plurality of magnets or a plurality of electromagnets disposed at a predetermined interval in the peripheral direction in the upper part of the deposit shield.

29. A plasma processing apparatus comprising:
a plasma processing chamber;
a susceptor which is disposed in the plasma processing chamber and on which a substrate to be processed is mounted;
an exhaust mechanism which exhausts the plasma processing chamber from beneath the susceptor; and
an exhausts ring having a plurality of exhaust holes that are formed in an annular shape to surround the susceptor, are different in the opening area, and are arranged so that the opening area of the exhaust holes disposed at the outer side of the exhaust ring is larger than the opening area of the exhaust holes disposed at the inner side of the exhaust ring.

30. The plasma processing apparatus according to claim 29, wherein at least three types of exhaust holes differing in the opening area are disposed in the exhaust ring so that the opening area is gradually increased from the inner side to the outer side of the exhaust ring.

31. The plasma processing apparatus according to claim 29, wherein the exhaust ring is varied in the plate thickness in gradual steps concentrically depending on the opening area of the exhaust holes.

32. The plasma processing apparatus according to claim 29, wherein a magnet to prevent leak of the plasma generated in the plasma processing chamber is provided at the exhaust ring.

33. The plasma processing apparatus according to claim 32, wherein the magnet is disposed in a plurality at an equal interval along the peripheral direction so that magnetic poles of the magnets are arranged along the peripheral direction of the exhaust ring.

34. The plasma processing apparatus according to claim 29, wherein the exhaust holes are circular holes, and the diameter of the exhaust holes of the largest opening area disposed at the outermost side is 5 to 20 mm.

35. The plasma processing apparatus according to claim 29, wherein a plasma is generated in the vacuum processing chamber, and the substrate is processed by etching.

36. An exhaust ring mechanism disposed in a plasma processing chamber of a plasma processing apparatus, formed in an annular shape to surround a susceptor on which a substrate to be processed is mounted, and having a plurality of exhaust holes that are provided in plural types different in the opening area and are arranged so that the opening area of the exhaust holes disposed at the outer side is larger than the opening area of the exhaust holes disposed at the inner side.

37. The exhaust ring mechanism according to claim 36, wherein at least three types of exhaust holes differing in the opening area are disposed so that the opening area is gradually increased from the inner side to the outer side.

38. The exhaust ring mechanism according to claim 36, wherein the plate thickness is varied in gradual steps concentrically depending on the opening area of the exhaust holes.

39. The exhaust ring mechanism according to claim 36, wherein a magnet to prevent leak of the plasma generated in the plasma processing chamber is provided.

40. The exhaust ring mechanism according to claim 39, wherein the magnet is disposed in a plurality at an equal interval along the peripheral direction so that magnetic poles of the magnets are arranged along the peripheral direction of the magnetic ring.

41. The exhaust ring mechanism according to claim 36, wherein the exhaust holes are circular holes, and the diameter of the exhaust holes of the largest opening area disposed at the outermost side is 5 to 20 mm.
